(19) United States
(12) Patent Application Publication
(10) Pub. No.: US 2025/0231470 A1
(43) Pub. Date: Jul. 17, 2025

(54) PROJECTION SYSTEM

(71) Applicant: SEIKO EPSON CORPORATION, Tokyo (JP)

(72) Inventors: Katsunori TANAKA, Azumino-shi (JP); Manae MIYATA, Matsukawa-mura (JP); Yoshitsugu AKUTAGAWA, Azumino-shi (JP)

(73) Assignee: SEIKO EPSON CORPORATION, Tokyo (JP)

(21) Appl. No.: 19/016,697

(22) Filed: Jan. 10, 2025

(30) Foreign Application Priority Data
Jan. 12, 2024 (JP) 2024-003307

(51) Int. Cl. G03B 21/16; G03B 21/14; H05K 7/20

(52) U.S. Cl. CPC G03B 21/16; G03B 21/145; H05K 7/20145

(57) ABSTRACT

A projection system includes a projector body configured to project modulated light frontward; a channel configured to guide air exhausted from the projector body; a fan configured to cause the air in the channel to flow; and a housing configured to house the projector body, the channel, and the fan. The channel includes an outflow port via which the air is discharged out of the housing. The housing includes a projection section through which the light projected from the projector body passes, an intake section configured to take in air outside the housing, and an exhaust section that overlaps with the outflow port when viewed in an air delivering direction of the fan and is configured to exhaust the air exhausted via the outflow port out of the housing. The projection section, the intake section, and the exhaust section are all provided at a frontward facing surface of the housing.

The present application is based on, and claims priority from JP Application Serial Number 2024-003307, filed Jan. 12, 2024, the disclosure of which is hereby incorporated by reference herein in its entirety.

### BACKGROUND

### 1. Technical Field

The present disclosure relates to a projection system.

### 2. Related Art

For example, JP-A-2015-036789 discloses a projection apparatus enclosure that houses a projection apparatus such as a projector. The projection apparatus enclosure is provided with a vent port via which air is guided into the enclosure and an exhaust port via which the air in the enclosure is exhausted out of the enclosure.

JP-A-2015-036789 is an example of the related art.

In the projection apparatus enclosure of the related art, the vent port and the exhaust port are provided at surfaces at right and left opposite sides, respectively, on the assumption that the projection direction is the frontward direction. In this case, when the surfaces at the right and left opposite sides of the projection apparatus enclosure are disposed close to a wall surface, or when other apparatuses are disposed at the right and left opposite sides of the projection apparatus enclosure, the wall surface, or the other apparatuses block the vent port or the exhaust port, so that the efficiency at which heat is dissipated from the projection apparatus enclosure may lower. Employing the projection apparatus enclosure of the related art therefore has a problem of a limited installation position of the projection system because the projection system cannot be disposed close to a wall surface or other apparatuses.

### SUMMARY

A projection system according to an aspect of the present disclosure includes a projector body configured to project modulated light frontward; a channel configured to guide air exhausted from the projector body; a fan configured to cause the air in the channel to flow; and a housing configured to house the projector body, the channel, and the fan. The housing includes a projection section through which the light projected from the projector body passes, an intake section configured to take in air outside the housing, and an exhaust section configured to exhaust the air exhausted from the channel out of the housing. The projection section, the intake section, and the exhaust section are all provided at a frontward facing surface of the housing.

### BRIEF DESCRIPTION OF THE DRAWINGS

FIG. 1 shows the state of an installed projection system according to an embodiment.

FIG. 2 is a diagrammatic plan view showing the internal structure of the projection system according to the embodiment.

FIG. 3 is a diagrammatic front view showing the internal structure of the projection system according to the embodiment.

FIG. 4 is a diagrammatic side view showing the internal structure of the projection system according to the embodiment.

FIG. 5 is a schematic configuration diagram showing a projector body in the embodiment.

FIG. 6 shows the state of the installed projection system according to a variation of the embodiment.

### DESCRIPTION OF EMBODIMENTS

A projection system 100 according to an embodiment of the present disclosure will be described below with reference to the drawings. Note that the scope of the present disclosure is not limited to the embodiment below, and can be changed in any manner within the scope of the technical idea of the present disclosure. In the following drawings, for clarity of each configuration, the scale, the number, and other factors of each structure differ from those of an actual structure in some cases.

An XYZ coordinate system is shown as appropriate in each of the drawings. The X-axis direction and the Y-axis direction are horizontal directions perpendicular to the Z-axis direction and perpendicular to each other. In the following description, the direction parallel to the Z-axis direction is called an upward-downward direction z, the direction parallel to the X-axis direction is called a frontward-rearward direction X, and the direction parallel to the Y-axis direction is called a rightward-leftward direction Y. The +Z direction is called upward, the −Z direction is called downward, the +X direction is called frontward, the −X direction is called rearward, the +Y direction is called leftward, and the −Y direction is called rightward.

In the present specification, the direction in which light modulated by the projection system 100 is projected is defined as a frontward direction. In the projection system 100 according to the embodiment, the +X direction is the frontward direction, and the −X direction is the rearward direction. Note that the projection system 100 in use does not necessarily have a specific posture, and even when the projection system 100 is used in any posture, the direction in which the projection system 100 projects light is the frontward direction, and the direction opposite the frontward direction is the rearward direction.

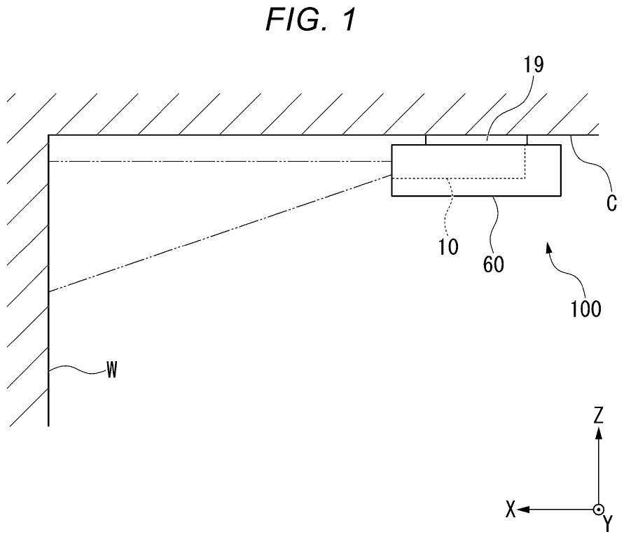

FIG. 1 shows the state of the installed projection system 100 according to the present embodiment. The projection system 100 according to the embodiment is installed at a ceiling surface C facing downward (−Z direction). For example, a mount 19 is installed at the ceiling surface C, and the projection system 100 is fixed to the mount 19. The projection system 100 projects light toward a wall surface W perpendicular to the ceiling surface C. The mount 19 is a mechanism having the function of attaching and fixing the projection system 100 to an installation target such as the ceiling surface C or the wall surface W, and may, for example, be a ceiling hanger that attaches the projection system 100 to the ceiling surface C. For example, when the projection system 100 is installed in a stable manner when placed at a placement surface that will be described later, the mount 19 may be omitted. The projection system may instead have the function of the mount 19.

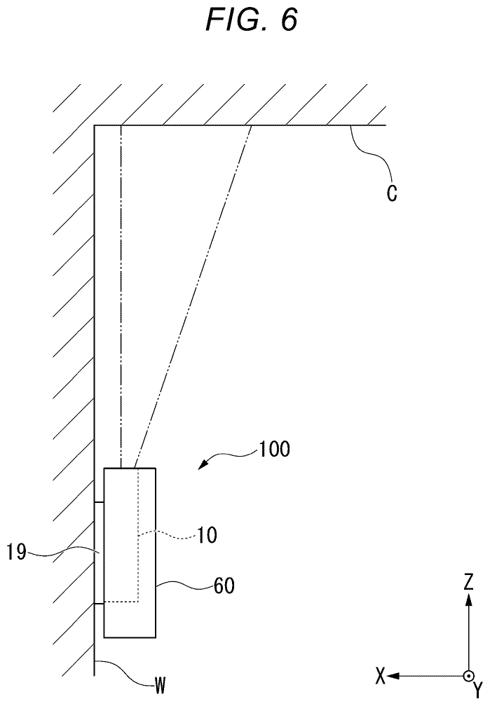

Note that the projection system 100 may not necessarily be fixed to the ceiling surface C. As will be described later with reference to FIG. 6, the projection system 100 may be fixed to the wall surface W. The projection system 100 may be used in a horizontally installed state in which the projection system 100 is placed at a placement surface such as a table.

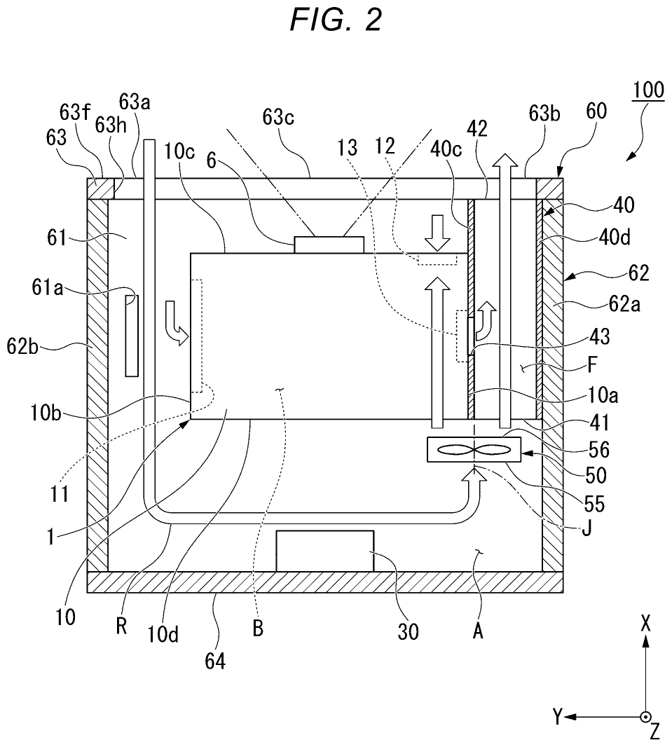

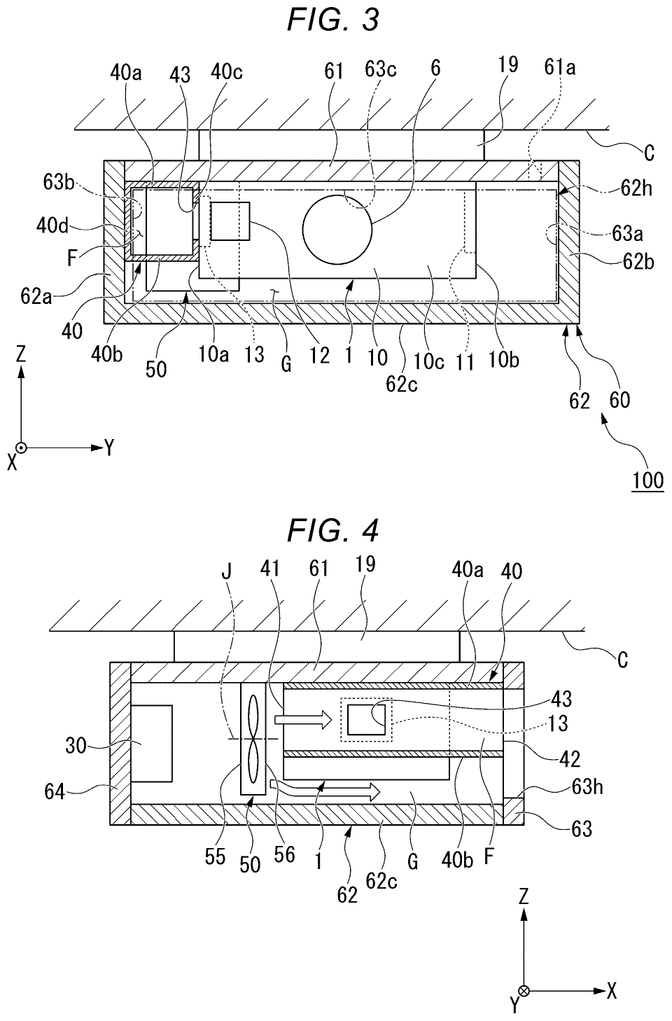

FIG. 2 is a diagrammatic plan view showing the internal structure of the projection system 100 according to the embodiment. FIG. 3 is a diagrammatic front view showing the internal structure of the projection system 100 according to the embodiment. FIG. 4 is a diagrammatic side view showing the internal structure of the projection system 100 according to the embodiment.

The projection system 100 includes a projector body 1, a heat generator 30, a channel 40, a fan 50, and a housing 60, as shown in FIGS. 2, 3, and 4. The projector body 1, the heat generator 30, the channel 40, and the fan 50 are housed in an internal space A of the housing 60.

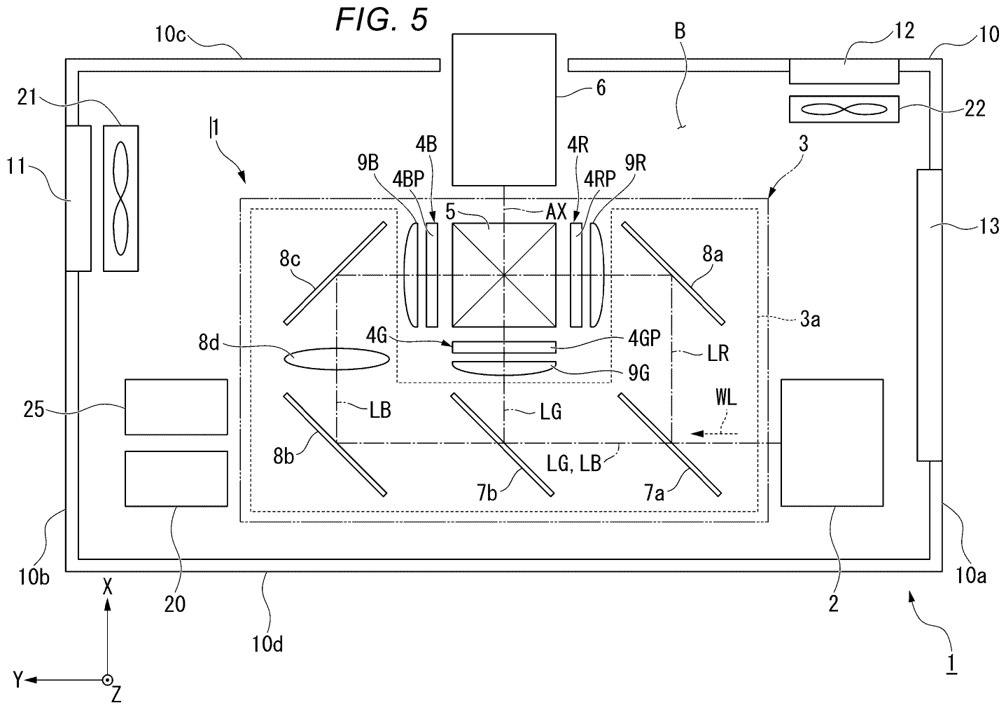

FIG. 5 is a schematic configuration diagram showing the projector body 1 in the present embodiment. The projector body 1 projects the modulated light frontward (+X direction). The projector body 1 is fixed to the inner surface of the housing 60 and supported by the housing 60.

The projector body 1 includes a light source 2, a light guiding system 3, a projection optical apparatus 6, a power supply apparatus 20, a controller 25, a first internal fan 21, a second internal fan 22, and an inner case 10. The light source 2, the light guiding system 3, the projection optical apparatus 6, the power supply apparatus 20, the controller 25, the first internal fan 21, and the second internal fan 22 are housed in the inner case 10.

The light source 2 outputs illumination light WL adjusted to have a substantially uniform illuminance distribution toward a color separation system 3a. The light source 2 is, for example, a semiconductor laser. The light guiding system 3 guides the light output from the light source 2 to the projection optical apparatus 6. The light guiding system 3 includes the color separation system 3a, light modulating units 4R, 4G, and 4B, and a light combining system 5. The light modulating unit 4R includes a light modulator 4RP. The light modulating unit 4G includes a light modulator 4GP. The light modulating unit 4B includes a light modulator 4BP.

The color separation system 3a separates the illumination light WL from the light source 2 into red light LR, green light LG, and blue light LB. The color separation system 3a includes a first dichroic mirror 7a, a second dichroic mirror 7b, a first reflection mirror 8a, a second reflection mirror 8b, a third reflection mirror 8c, and a relay lens 8d.

The first dichroic mirror 7a separates the illumination light WL output from the light source 2 into the red light LR and light that is the mixture of the green light LG and the blue light LB. The first dichroic mirror 7a is characterized by reflecting the red light LR and transmitting the green light LG and the blue light LB. The second dichroic mirror 7b separates the light that is the mixture of the green light LG and the blue light LB into the green light LG and the blue light LB. The second dichroic mirror 7b is characterized by reflecting the green light LG and transmitting the blue light LB.

The first reflection mirror 8a is disposed in the optical path of the red light LR and reflects the red light LR reflected off the first dichroic mirror 7a toward the light modulator 4RP. The second reflection mirror 8b and the third reflection mirror 8c are disposed in the optical path of the blue light LB and guide the blue light LB having passed through the second dichroic mirror 7b to the light modulator 4BP.

The light modulators 4RP, 4GP, and 4BP are each configured with a liquid crystal panel. The light modulator 4RP modulates the red light LR out of the light output from the light source 2 in accordance with an image signal. The light modulator 4GP modulates the green light LG out of the light output from the light source 2 in accordance with an image signal. The light modulator 4BP modulates the blue light LB out of the light output from the light source 2 in accordance with an image signal. The light modulators 4RP, 4GP, and 4BP thus each form image light corresponding to the relevant color light. Although not shown, polarizers are disposed at the light incident side and the light exiting side of each of the light modulators 4RP, 4GP, and 4BP.

A field lens 9R, which parallelizes the red light LR to be incident on the light modulator 4RP, is disposed at the light incident side of the light modulator 4RP. A field lens 9G, which parallelizes the green light LG to be incident on the light modulator 4GP, is disposed at the light incident side of the light modulator 4GP. A field lens 9B, which parallelizes the blue light LB to be incident on the light modulator 4BP, is disposed at the light incident side of the light modulator 4BP.

The light combining system 5 is configured with a cross dichroic prism having a substantially cubic shape. The light combining system 5 combines the red image light from the light modulator 4RP, the green image light from the light modulator 4GP, and the blue image light from the light modulator 4BP with one another. The light combining system 5 outputs the combined image light toward the projection optical apparatus 6. In the present embodiment, the light combining system 5 outputs the light frontward (+X direction).

In the present embodiment, the projection optical apparatus 6 is located at a position shifted frontward (+X direction) from the light combining system 5. The projection optical apparatus 6 enlarges the light output from the light guiding system 3 and projects the enlarged light frontward. The projection optical apparatus 6 includes, for example, multiple lenses. The light output from the light guiding system 3 in the present embodiment is the combined image light from the light combining system 5, that is, the light modulated by the light modulators 4RP, 4GP, and 4BP. When the light is projected from the projection optical apparatus 6, enlarged color images (video) are displayed at a projection target of the projection system 100.

The power supply apparatus 20 supplies each section of the projector body 1 with power supplied from an external power supply coupled to the projector body 1. The controller 25 is configured with a computer or an integrated circuit that incorporates processes in the form of a program that are carried out by drivers that drive the light source 2, the light modulators 4RP, 4GP, and 4BP, the power supply apparatus 20, the first internal fan 21, the second internal fan 22, and the like. For example, the controller 25 is configured with a processor. The controller 25 processes signals input to the projector body 1 from the external apparatuses and conveys the processed signals to the relevant sections of the projector body 1.

The first internal fan 21 and the second internal fan 22 send air to cooling targets housed in the inner case 10 to cool the cooling targets. The first internal fan 21 and the second internal fan 22 may each be any of an axial flow fan, a centrifugal fan, and a sirocco fan, or may be a fan of any other type. The targets to be cooled in the projector body 1 in the present embodiment are, for example, the power supply apparatus 20, the controller 25, and the light modulating units 4R, 4G, and 4B. A duct-shaped channel that is not shown may be provided in the inner case 10. In this case, airflows generated by the first internal fan 21 and the second internal fan 22 are sent to the cooling targets through the channel.

The inner case 10 constitutes the exterior of the projector body 1. The inner case 10 has the shape of a substantially cuboid box configured with multiple walls. An in-case space B surrounded by the multiple walls is formed in the inner case 10. The outer surface of the inner case 10 has a first side surface 10a, a second side surface 10b, a third side surface 10c, and a fourth side surface 10d. The first side surface 10a is provided at a wall that covers the in-case space B from the left (+Y direction) and faces rightward (−Y direction). The second side surface 10b is provided at a wall that covers the in-case space B from the right (−Y direction) and faces leftward (+Y direction). The third side surface 10c is provided at a wall that covers the in-case space B from the front (+X direction) and faces frontward (+X direction). The fourth side surface 10d is provided at a wall that covers the in-case space B from the rear (−X direction) and faces rearward (−X direction). The inner case 10 further has, as the outer surface, a top surface provided at a wall that covers the in-case space B from below (−Z direction) and facing upward (+Z direction) and a bottom surface provided at a wall that covers the in-case space B from above (+Z direction) and facing downward (−Z direction).

The inner case 10 in the present embodiment is provided with a first intake port 11, a second intake port 12, and an exhaust port 13. The first intake port 11, the second intake port 12, and the exhaust port 13 cause the in-case space B to communicate with the external space of the inner case 10.

The first intake port 11 is provided at the wall that covers the in-case space B from the left (+Y direction) out of the multiple walls of the inner case 10. The first intake port 11 therefore opens through the second side surface 10b. The first intake port 11 faces the first internal fan 21 in the rightward-leftward direction Y in the in-case space B. The first internal fan 21 guides the air outside the inner case 10 to the in-case space B via the first intake port 11.

The second intake port 12 is provided at the wall that covers the in-case space B from the front (+X direction). The second intake port 12 therefore opens through the third side surface 10c. The second intake port 12 faces the second internal fan 22 in the frontward-rearward direction X in the in-case space B. The second internal fan 22 guides the air outside the inner case 10 to the in-case space B via the second intake port 12.

The exhaust port 13 is provided at the wall that covers the in-case space B from the right (−Y direction) out of the multiple walls of the inner case 10. The exhaust port 13 therefore opens through the first side surface 10a. The exhaust port 13 discharges the air introduced into the in-case space B via the first intake port 11 and the second intake port 12 by the first internal fan 21 and the second internal fan 22 to the space outside the inner case 10.

The projector body 1 is disposed in the housing 60, as shown in FIG. 2. The air introduced into the inner case 10 via the first intake port 11 and the second intake port 12 is the air in the internal space A of the housing 60. The air in the inner case 10 is discharged to the internal space A of the housing 60 via the exhaust port 13.

The projector body 1 is disposed substantially at the center of the internal space A of the housing 60 in the rightward-leftward direction Y. The projector body 1 is further disposed at a position biased frontward (+X direction) in the frontward-rearward direction X in the internal space A of the housing 60.

The housing 60 has the shape of a substantially cuboid box having multiple walls that surround the internal space A. The housing 60 in the present embodiment includes a base plate 61, a primary cover 62, a front cover 63, and a rear cover 64. The primary cover 62, the front cover 63, and the rear cover 64 are fixed to the base plate 61.

The base plate 61 has the shape of a rectangular plate extending along a plane perpendicular to the upward-downward direction Z, as shown in FIG. 3. The base plate 61 covers the internal space A from above (+Z direction). The base plate 61 is fixed to the ceiling surface C via the mount 19. The base plate 61 therefore extends along the ceiling surface C, at which the projection system 100 is installed. The upper surface of the base plate 61 faces the ceiling surface C with a gap therebetween. The projector body 1, the fan 50, and the channel 40 are fixed to the lower surface of the base plate 61.

Although not shown, the rear cover 64 is provided with a connector that couples the projection system 100 to the external power supply. Note that the connector may instead be provided at a first sidewall 62a or a second sidewall 62b of the primary cover 62, the front cover 63, or the rear cover 64.

The base plate 61 is provided with an intake hole 61a. The intake hole 61a passes through the base plate 61 in the thickness direction (that is, upward-downward direction Z). The intake hole 61a guides the air outside the housing 60 to the internal space A. The intake hole 61a in the present embodiment is located on the left (+Y direction) of the first intake port 11 of the projector body 1 when viewed in the upward-downward direction Z. The air flowing into the internal space A via the intake hole 61a is primarily guided into the projector body 1 via the first intake port 11.

The intake hole 61a in the present embodiment is provided in the base plate 61 extending along the ceiling surface C. The intake hole 61a is therefore unlikely to be visually recognized by a resident in the room in which the projection system 100 is installed. That is, according to the present embodiment, the intake hole 61a is unlikely to impair the artistic design of the projection system 100. The housing 60 in the present embodiment is provided with an intake section 63a, which guides air from the space in front of the housing 60 to the internal space A of the housing 60. The housing 60 may therefore not necessarily have the intake hole 61a.

The primary cover 62 includes a lower wall 62c, the first sidewall 62a, and the second sidewall 62b. The lower wall 62c has the shape of a rectangular plate extending along the plane perpendicular to the upward-downward direction Z. The first sidewall 62a and the second sidewall 62b both have the shape of a rectangular plate extending along a plane perpendicular to the rightward-leftward direction Y.

The lower wall 62c is located below the base plate 61 (−Z direction). The lower wall 62c faces the base plate 61 in the upward-downward direction Z via the internal space A. The lower wall 62c covers the internal space A from below (−Z direction). The upper surface of the lower wall 62c faces the lower surface of the inner case 10 via a gap G. The gap G extends along the frontward-rearward direction X, as shown in FIG. 4.

The first sidewall 62a and the second sidewall 62b face each other in the rightward-leftward direction Y via the internal space A, as shown in FIG. 3. The first sidewall 62a extends upward (+Z direction) from the right (−Y direction) edge of the lower wall 62c. The first sidewall 62a covers the internal space A from the right. The second sidewall 62b extends upward (+Z direction) from the left (+Y direction) edge of the lower wall 62c. The second sidewall 62b covers the internal space A from the left.

The first sidewall 62a and the first side surface 10a of the projector body 1 face each other via a gap, as shown in FIG. 2. The channel 40 is disposed between the first sidewall 62a and the first side surface 10a.

The second sidewall 62b and the second side surface 10b of the projector body 1 face each other via a gap. A portion of an air delivery path R, which will be described later, is formed between the second sidewall 62b and the second side surface 10b.

The rear cover 64 covers the internal space A from the rear (−X direction), as shown in FIG. 2. The rear cover 64 has the shape of a rectangular plate extending along a plane perpendicular to the frontward-rearward direction X. The rear cover 64 is attached to the rear end of the base plate 61 and the rear end of the primary cover 62. The heat generator 30 is fixed to the rear cover 64.

The rear cover 64 and the fourth side surface 10d of the projector body 1 face each other via a gap. A portion of the air delivery path R, which will be described later, is formed between the rear cover 64 and the fourth side surface 10d.

The front cover 63 covers the internal space A from the front (+X direction). The front cover 63 has the shape of a rectangular plate extending along the plane perpendicular to the frontward-rearward direction X. The front cover 63 is attached to the front end of the base plate 61 and the front end of the primary cover 62. The front cover 63 has a front surface 63f facing frontward (+X direction). That is, the housing 60 has the front surface 63f facing frontward.

The front cover 63 is provided with an opening 63h. The opening 63h opens through the front surface 63f. The opening 63h passes through the front cover 63 in the thickness direction (that is, frontward-rearward direction X).

The opening 63h in the present embodiment has a rectangular shape the longitudinal direction of which is the rightward-leftward direction Y, as indicated by a two-dot chain line in FIG. 3. The opening 63h is provided with the intake section 63a, an exhaust section 63b, and a projection section 63c. That is, the housing 60 includes the intake section 63a, the exhaust section 63b, and the projection section 63c.

The intake section 63a is a region of the opening 63h via which the air outside the housing 60 is taken into the internal space A. The region of the opening 63h in the present embodiment other than the exhaust section 63b functions as the intake section 63a.

The exhaust section 63b is a region of the opening 63h via which the air in the internal space A discharges out of the housing 60. The exhaust section 63b exhausts the air discharged via an outflow port 42 of the channel 40 out of the housing 60. The exhaust section 63b further exhausts the air passing through the gap G between the inner surface of the housing 60 and the projector body 1 out of the housing 60. The exhaust section 63b in the present embodiment is a region that overlaps with the fan 50 when viewed in the frontward-rearward direction. Furthermore, the exhaust section 63b in the present embodiment overlaps with the outflow port 42 of the channel 40 when viewed in the frontward-rearward direction or the air delivering direction of the fan 50, which will be described later.

The projection section 63c is a region of the opening 63h via which the light projected from the projector body 1 passes. The projection section 63c overlaps with the projection optical apparatus 6 when viewed in the frontward-rearward direction X. Note that the projection section 63c in the present embodiment also functions as the intake section 63a.

The heat generator 30 is a part that adds a function to the projector body 1 in the projection system 100. The heat generator 30 is, for example, an audio instrument, a battery, or a light source. The heat generator 30 generates heat when driven. The heat generator 30 is located at the rear (−X direction) of the projector body 1. The heat generator 30 is disposed substantially at the center of the internal space A of the housing 60 in the rightward-leftward direction Y.

When the heat generator 30 is an audio instrument, the heat generator 30 includes, for example, multiple loudspeakers that emit sounds that belong to various sound ranges. When the heat generator 30 is a battery, the heat generator 30 is coupled to the projector body 1 and supplies the projector body 1 with electric power. When the heat generator 30 is a light source, the heat generator 30 outputs light out of the projection system 100 to notify a person outside the projection system 100, for example, of the state of the projection system 100 or illuminate the surroundings of the projection system 100.

The channel 40 is a member that forms an air path F, which guides air in one direction (frontward-rearward direction X in present embodiment). The channel 40 in the present embodiment is a duct configured with multiple side plates 40a, 40b, 40c, and 40d. The channel 40 extends along the frontward-rearward direction X. The channel 40 is located between the first side surface 10a of the projector body 1 and the first sidewall 62a of the housing 60 in the internal space A thereof.

The channel 40 includes a first side plate 40a, a second side plate 40b, a third side plate 40c, and a fourth side plate 40d, as shown in FIG. 3. The first side plate 40a, the second side plate 40b, the third side plate 40c, and the fourth side plate 40d are combined with each other into a rectangular shape when viewed in the frontward-rearward direction X. The first side plate 40a, the second side plate 40b, the third side plate 40c, and the fourth side plate 40d surround the air path F from the above, below, right, and left.

The first side plate 40a and the second side plate 40b extend along the plane perpendicular to the upward-downward direction Z. The first side plate 40a and the second side plate 40b face each other in the upward-downward direction Z. The first side plate 40a is located above the second side plate 40b. The first side plate 40a is disposed along the base plate 61 of the housing 60. The second side plate 40b faces the lower wall 62c of the housing 60 via a gap in the upward-downward direction Z.

The third side plate 40c and the fourth side plate 40d extend along the plane perpendicular to the rightward-leftward direction Y. The third side plate 40c and the fourth side plate 40d face each other in the rightward-leftward direction Y. The third side plate 40c is located on the left (+Y direction) of the fourth side plate 40d. The third side plate 40c is disposed along the first side surface 10a of the projector body 1. The fourth side plate 40d is disposed along the first sidewall 62a of the housing 60.

The channel 40 has an inflow port 41, the outflow port 42, and a side hole 43, as shown in FIG. 2. The inflow port 41 is located at the rear (−X direction) end of the channel 40. The inflow port 41 causes the air path F to open rearward. The outflow port 42 is located at the front (+X direction) end of the channel 40. The outflow port 42 causes the air path F to open frontward. The outflow port discharges the air out of the housing 60. The outflow port 42 in the present embodiment is located at a position shifted frontward (+X direction) from the projector body 1. The air passing through the air path F and flowing out frontward via the outflow port 42 is therefore unlikely to hit the projector body 1.

The side hole 43 is provided in the third side plate 40c. The side hole 43 passes through the third side plate 40c in the thickness direction (that is, rightward-leftward direction Y). The side hole 43 overlaps the exhaust port 13 of the projector body 1 when viewed in the rightward-leftward direction Y, as shown in FIG. 4. The side hole 43 thus leads to the exhaust port 13. The side hole 43 and the exhaust port 13 cause the in-case space B of the projector body 1 to communicate with the air path F. The air in the in-case space B discharged via the exhaust port 13 is guided to the air path F via the side hole 43.

The fan 50 generates an airflow in the housing 60, as shown in FIG. 2. The fan 50 is coupled, for example, to the projector body 1 and is driven in synchronization with the operation of driving the projector body 1.

The fan 50 suctions air from the rear (−X direction) and blows the air out frontward (+X direction). That is, the air delivering direction of the fan 50 is the frontward direction (+X direction). The fan 50 includes a suction section 55, which suctions air, and a blowout section 56, which blows the air out. The suction section 55 in the present embodiment is provided at the rear-facing surface of the fan 50. The blowout section 56 in the present embodiment is provided at the front-facing surface of the fan 50.

The fan 50 in the present embodiment is an axial flow fan having rotary blades that rotate around an axis of rotation J extending in the frontward-rearward direction X. Note that the fan 50 may be a centrifugal fan or a sirocco fan. The fan 50 is located in the housing 60 and behind the projector body 1 and the channel 40.

The fan 50 overlaps with the inflow port 41 of the channel 40 when viewed from the air delivering direction of the fan 50 (frontward direction in present embodiment), as shown in FIG. 3. The fan 50 thus sends air to the inflow port 41 of the channel 40 to form an airflow in the air path F traveling from the inflow port 41 toward the outflow port 42. That is, the fan 50 causes the air to flow inside the channel 40 (that is, air path F). The air flowing frontward in the air path F is blown out frontward via the outflow port 42.

The fan 50 in the present embodiment overlaps with the projector body 1 when viewed in the air delivering direction of the fan 50 (frontward direction in present embodiment). The fan 50 thus applies the air to the outer surface of the projector body 1 as well as to the air path F to cool the outer surface of the projector body 1. Note that the inner case 10 of the projector body 1 may be provided with a through hole via which the air blown out from the fan 50 is guided to the in-case space B. In this case, the air from the fan 50 can be guided to the in-case space B of the inner case 10, so that the in-case space B can be directly cooled by the fan 50.

Furthermore, the fan 50 in the present embodiment overlaps with the gap G provided between the projector body 1 and the inner surface of the housing 60 when viewed in the air delivering direction of the fan 50 (frontward direction in present embodiment). The air blown out from the fan 50 passes through the gap G, as shown in FIG. 4. That is, the fan 50 causes the air to flow along the outer surface of the projector body 1 in the exterior of the channel 40 in addition to the interior of the channel 40. The air blown out from the fan 50 absorbs heat from the outer surface of the projector body 1 when passing through the gap G to cool the projector body 1.

The flow of the air in the internal space A of the housing 60 will next be described with reference to FIG. 2.

When the projector body 1 is driven, the projector body 1 takes air into the in-case space B via the first intake port 11 and the second intake port 12, and discharges the air heated by the apparatuses to be cooled in the projector body 1 via the exhaust port 13.

The first intake port 11 guides the following two types of air into the projector body 1: the air flowing into the internal space A of the housing 60 via the opening 63h and flowing along the second side surface 10b of the projector body 1; and the air flowing into the internal space A via the intake hole 61a.

The second intake port 12 faces the opening 63h. The second intake port 12 therefore directly guides the air flowing into the internal space A of the housing 60 via the opening 63h into the projector body 1.

The exhaust port 13 leads to the side hole 43 of the channel 40. The air exhausted via the exhaust port 13 therefore flows into the air path F in the channel 40.

The fan 50 is driven along with the projector body 1. When the fan 50 is driven, the air blown out from the fan 50 flows into the inflow port 41 of the channel 40 and the gap G. The air flowing into the inflow port 41 forms a frontward airflow in the air path F in the channel 40. The exhaust air flowing into the air path F from the projector body 1 thus flows out frontward via the outflow port 42 along with the airflow formed by the fan 50. Since the outflow port 42 faces the opening 63h in the frontward-rearward direction X, the air flowing out via the outflow port 42 is discharged out of the housing 60 via the opening 63h of the housing 60.

The fan 50 suctions air from the suction section 55 facing the rear of the fan 50 (−X direction) and blows the air out frontward from the blowout section 56 facing frontward. The pressure at the rear of the fan 50 is therefore negative pressure. The fan 50 forms an airflow toward the suction section 55 in the housing 60.

When the projection system is viewed in the frontward-rearward direction, most of the opening 63h overlaps with the projector body 1 or the channel 40, as shown in FIG. 3. The opening 63h is therefore widely open frontward in the vicinity of the left-side (+Y direction) end of the opening 63h, and this portion of the opening 63h primarily functions as the intake section 63a. That is, the inflow of the air via the opening 63h in the present embodiment is dominant in the vicinity of the left-side (+Y direction) end of the opening 63h.

The air flowing in via the intake section 63a located at the left-side end of the opening 63h flows rearward between the second side surface 10b of the projector body 1 and the second sidewall 62b of the housing 60, as shown in FIG. 2. Furthermore, the air flows rightward (−Y direction) between the projector body 1 and the rear cover 64, and is suctioned into the fan 50 from the suction section 55 of the fan 50.

The path of air from the intake section 63a to the suction section 55 of the fan 50 is called the air delivery path R. That is, the air delivery path R is provided in the housing 60. The air delivery path R extends along the outer surface (second side surface 10b and fourth side surface 10d) of the projector body 1. In the present embodiment, the heat generator 30 is disposed in the air delivery path R. The heat generator 30 is cooled by the air flowing through the air delivery path R. Note that the air delivery path R may extend not only along the outer surface of the projector body 1 but also along the top surface and the bottom surface of the projector body 1.

Effects and advantages of the projection system 100 according to the present embodiment will next be described.

The projection section 63c of the housing 60 transmits the light projected from the projector body 1. The housing 60 is so disposed that the surface at which the projection section 63c is provided is separate from another apparatus or a wall surface in order not to block the travel of the light passing through the projection section 63c. The intake section 63a guides air from the exterior of the housing 60 to the internal space A, and the exhaust section 63b exhausts the air in the internal space A of the housing 60 out of the housing 60. The housing 60 is so disposed that the surface at which the intake section 63a and the exhaust section 63b are provided is separate from another apparatus or a wall surface in order not to block the air suctioned from the intake section 63a and the air exhausted from the exhaust section 63b. In a housing of related art, the projection section, the intake section, and the exhaust section are provided at portions of the outer surface of the housing 60 that differ from one another. Therefore, in the housing of related art, it is necessary to separate the three portions of the outer surface from another apparatus or a wall surface, so that the projection system is installed at a greatly limited position.

In contrast, the projection system 100 according to the present embodiment, the projection section 63c, the intake section 63a, and the exhaust section 63b are all provided at the front surface 63f of the housing 60. According to the present embodiment, the surfaces of the housing 60 other than the front surface 63f can be brought close to another apparatus or a wall surface. That is, the present embodiment allows the projection system 100 to be installed with increased flexibility while maintaining the efficiency of the operation of suctioning and exhausting air into and out of the internal space A of the housing 60 and suppressing a decrease in the efficiency at which heat is dissipated from the projector body 1.

Examples of the other apparatus disposed adjacent to the projection system 100 may include other projection systems 100, light emitting instruments, and audio instruments. In particular, conceivable examples in which one projection system 100 is disposed adjacent to another projection system 100 may include stack projection, multi-projection, and blending projection. In the stack projection, a stack of multiple projection systems 100 is arranged in the upward-downward direction Z, and performs projection from multiple projection systems 100 onto a projection target. In the multi-projection or the blending projection, multiple projection systems 100 are arranged side by side in the rightward-leftward direction Y, and perform projection onto a projection target. According to the present embodiment, even when multiple projection systems 100 are arranged adjacent to each other in the upward-downward or rightward-leftward direction and perform stack projection, multi-projection, or blending projection, the intake section 63a and the exhaust section 63b of each of the projection systems 100 do not face each other. The present embodiment can therefore prevent one of the projection systems 100 from suctioning the air exhausted from the exhaust section 63b of any of the other multiple projection systems 100, and is likely to maintain the efficiency at which heat is dissipated from the projector body 1 of each of the projection systems 100.

In the projection system 100 according to the present embodiment, the projection section 63c, the intake section 63a, and the exhaust section 63b are intensively provided at one surface (front surface 63f) of the housing 60. The present embodiment can widen a range over which the occupant in the room in which the projection system 100 is installed cannot visually recognize the projection section 63c, the intake section 63a, and the exhaust section 63b, as compared with a case where the projection section, the intake section, and the exhaust section are provided at multiple portions of the outer surface of the housing 60. The artistic design of the projection system 100 can thus be improved.

The projection system 100 according to the embodiment includes the channel 40, which guides the air exhausted from the projector body 1, and the fan 50, which causes the air inside the channel 40 to flow. The housing 60 includes the exhaust section 63b, which overlaps with the outflow port 42 when viewed in the air delivering direction of the fan 50 and exhausts the air discharged from the channel 40 out of the housing 60. According to the present embodiment, the air exhausted from the projector body 1 and guided through the channel 40 can be exhausted by the fan 50 out of the housing 60. The present embodiment can thus prevent the air exhausted from the projector body 1 from staying in the internal space A of the housing 60 to increase the efficiency at which heat is dissipated from the projector body 1.

The fan 50 in the present embodiment overlaps with the gap G between the projector body 1 and the inner surface of the housing 60 in addition to the inflow port 41 of the channel 40 when viewed in the air delivering direction of the fan 50 (frontward direction in present embodiment), as shown in FIG. 3. According to the present embodiment, the fan 50 allows the air to flow along the outer surface of the projector body 1 in the exterior of the channel 40 in addition to the interior of the channel 40. The outer surface of the projector body 1 can therefore be cooled by the air blown out from the fan 50.

In the present embodiment, the fan 50 overlaps with the projector body 1 when viewed in the air delivering direction of the fan 50. According to the present embodiment, the air blown out from the fan 50 can be applied onto the outer surface of the projector body 1 to directly cool the outer surface of the projector body 1.

The projection system 100 according to the embodiment includes the heat generator 30, which is housed in the housing 60 and is an element different from the projector body, as shown in FIG. 2. Furthermore, the air delivery path R extending along the outer surface of the projector body 1 from the intake section 63a to the suction section 55 of the fan 50 is provided in the housing 60 in the present embodiment. The heat generator 30 in the present embodiment is disposed in the air delivery path R. According to the present embodiment, the heat generator 30 can be cooled by the air flowing through the air delivery path R, so that the reliability of the operation of the heat generator 30 can be increased.

The front end of the channel 40 (that is, outflow port 42) in the present embodiment is located at a position shifted frontward (+X direction) from the first intake port 11 and the second intake port 12 of the projector body 1. The exhaust air blown out frontward via the outflow port 42 is therefore unlikely to flow into the projector body 1 via the first intake port 11 or the second intake port 12. According to the present embodiment, low-temperature air is likely to be guided into the projector body 1 via the first intake port 11 and the second intake port 12, so that heat can be dissipated from the projector body 1 at increased efficiency.

### Variations

FIG. 6 shows the state of the installed projection system 100 according to a variation of the embodiment described above. In the installation state in the present variation, the upper side (+Z direction) corresponds to the front side of the projection system 100 and the projector body 1.

In the installation state in the present variation, the projection system 100 is installed at the wall surface W. In the present variation, the projection system 100 is attached to the wall surface W with the projection system 100 rotated by 90° around an axis extending in the rightward-leftward direction Y, as compared with the embodiment described above (see FIG. 1). In the installation state in the present variation, the projection system 100 outputs the image light upward (+Z direction). In the present variation, the light output from the projector body 1 is projected onto the ceiling surface C perpendicular to the wall surface W.

In addition to the above, embodiments of the present disclosure are not limited to the embodiment described above, and the following configurations and methods can be employed. The aforementioned embodiment has been described with reference to the case where the projector body 1 is provided with the two intake ports 11 and 12 and the one exhaust port 13, and the number of the intake ports and the number of the exhaust ports of the projector body 1 are not limited thereto. Furthermore, the intake ports 11 and 12 and the exhaust port 13 of the projector body 1 may be provided at any portions of the outer surface of the projector body 1 to the extent that the functions of the three ports can be provided.

In the embodiment described above, the projection system 100 includes the duct-shaped channel 40, which is the combination of the plate-shaped members and surrounds the air path F. In the projection system 100, however, the channel 40, which guides the air in one direction, may be configured by using some of the members disposed in the housing 60. As an example, the air path F may be a space surrounded by the outer surface of the projector body 1 and the inner surface of the housing 60. In this case, the outer surface of the projector body 1 and the inner surface of the housing 60 constitute the channel 40. That is, the “channel” in the present specification is not necessarily configured with specific members and may be configured with any members that constitute the air path F, which guides air in one direction.

In the embodiment described above, the channel 40 extends linearly in the frontward-rearward direction X. The channel 40 may, however, extend obliquely with respect to the frontward-rearward direction X or may be bent in the middle.

The aforementioned embodiment has been described with reference to the case where the fan 50 blows out air toward the inflow port 41 of the channel 40. The fan 50, however, does not necessarily have the configuration in the embodiment described above and may be any fan 50 that can form an airflow in the channel 40. For example, the fan 50 may be disposed so as to suction air via the outflow port 42 of the channel 40. In this case, the fan 50 is located at a position shifted frontward (+X direction) from the channel 40, and the suction section 55 faces the outflow port 42.

The aforementioned embodiment has been described with reference to the case where the intake section 63a, the exhaust section 63b, and the projection section 63c are each a region of the single opening 63h. That is, the opening 63h in the embodiment described above does not have partitions or the like that separate the intake section 63a, the exhaust section 63b, and the projection section 63c from each other. The intake section 63a, the exhaust section 63b, and the projection section 63c may instead be regions separate from each other. The projection section 63c may be provided with a light transmissive cover made of glass or the like. The intake section 63a and the exhaust section 63b may each be provided with a filter that removes dust and the like from the air passing therethrough.

In the embodiment described above, the intake section 63a, the exhaust section 63b, and the projection section 63c are provided at the front surface 63f of the housing 60, but not necessarily. The intake section, the exhaust section, and the projection section may each be formed not only at the front surface 63f of the housing 60 but also one or more of the first sidewall 62a, the second sidewall 62b, the lower wall 62c, and the base plate 61 coupled to the front surface 63f. That is, a portion of each of the intake section, the exhaust section, and the projection section may be provided at one or more of the first sidewall 62a, the second sidewall 62b, the lower wall 62c, and the base plate 61.

The aforementioned embodiment has been described with reference to the case where the housing 60 includes the front cover 63, which is provided with the window-shaped opening 63h. The housing 60 may, however, so configured that the front cover 63 is omitted and the entire internal space A is open frontward to form the opening 63h.

The aforementioned embodiment has been described with reference to the case where the present disclosure is applied to a transmissive projector, and the present disclosure is also applicable to a reflective projector. The term “transmissive” means that the light modulators including liquid crystal panels or the like transmit light. The term “reflective” means that the light modulators reflect light. Note that the light modulators are not limited to liquid crystal panels or the like, and may, for example, be light modulators using micromirrors.

The aforementioned embodiment has been described with reference to the projector body 1 using the three light modulating units 4R, 4G, and 4B, and the present disclosure is also applicable to a projector body using only one light modulator and a projector body using four or more light modulators.

The configurations and methods described in the present specification can be combined with each other as appropriate to the extent that no contradiction occurs.

### Summary of Present Disclosure

The present disclosure will be summarized below as additional remarks.

### Additional Remark 1

A projection system including:
a projector body configured to project modulated light frontward;
a channel configured to guide air exhausted from the projector body;
a fan configured to cause the air in the channel to flow; and
a housing configured to house the projector body, the channel, and the fan,
wherein the channel includes an outflow port via which the air is discharged out of the housing,
the housing includes
a projection section through which the light projected from the projector body passes,
an intake section configured to take in air outside the housing, and
an exhaust section that overlaps with the outflow port when viewed in an air delivering direction of the fan and is configured to exhaust the air exhausted via the outflow port out of the housing, and
the projection section, the intake section, and the exhaust section are all provided at a frontward facing surface of the housing.

The configuration described above, in which the projection section, the intake section, and the exhaust section are intensively disposed at the front surface of the housing, allows the surfaces of the housing other than the front surface to be brought close to another apparatus or a wall surface. The configuration described above therefore allows the projection system to be installed with increased flexibility while maintaining the efficiency of the operation of suctioning and exhausting air into and out of the internal space of the housing and suppressing a decrease in the efficiency at which heat is dissipated from the projector body. The configuration described above can further make the projection section, the intake section, and the exhaust section less visible, so that the projection system has a more artistic design than in a case where the projection section, the intake section, and the exhaust section are provided at multiple portions of the outer surface of the housing. According to the configuration described above, the air exhausted from the projector body and guided through the channel can be exhausted by the fan out of the housing. The present embodiment can thus prevent the air exhausted from the projector body from staying in the internal space of the housing to increase the efficiency at which heat is dissipated from the projector body.

### Additional Remark 2

The projection system according to the additional remark 1, wherein the fan causes the air to flow along an outer surface of the projector body in an exterior of the channel in addition to an interior of the channel.

According to the configuration described above, the outer surface of the projector body can be cooled by the air blown out from the fan.

### Additional Remark 3

The projection system according to the additional remark 1 or 2, wherein the fan overlaps with the projector body when viewed in the air delivering direction of the fan.

According to the configuration described above, the air blown out from the fan or the air suctioned into the fan can be applied onto the outer surface of the projector body to directly cool the outer surface of the projector body.

### Additional Remark 4

The projection system according to any one of the additional remarks 1 to 3, further including
a heat generator that is housed in the housing and is an element different from the projector body,
wherein an air delivery path that extends along an outer surface of the projector body from the intake section to a suction section of the fan is provided in the housing, and
the heat generator is disposed in the air delivery path.

According to the configuration described above, the heat generator can be cooled by the air flowing through the air delivery path, so that the reliability of the operation of the heat generator can be increased.

### Additional Remark 5

The projection system according to any one of the additional remarks 1 to 4, wherein a front end of the outflow port is located at a position shifted frontward from an intake port of the projector body.

According to the configuration described above, the exhaust air blown out frontward from the front end of the channel is unlikely to flow into the projector body via the intake port of the projector body. According to the present embodiment, low-temperature air is likely to be guided into the projector body, so that heat can be dissipated from the projector body at increased efficiency.

What is claimed is:

1. A projection system comprising:
a projector body configured to project modulated light frontward;
a channel configured to guide air exhausted from the projector body;
a fan configured to cause the air in the channel to flow; and
a housing configured to house the projector body, the channel, and the fan,
wherein the channel includes an outflow port via which the air is discharged out of the housing,
the housing includes
a projection section through which the light projected from the projector body passes,
an intake section configured to take in air outside the housing, and
an exhaust section that overlaps with the outflow port when viewed in an air delivering direction of the fan and is configured to exhaust the air exhausted via the outflow port out of the housing, and
the projection section, the intake section, and the exhaust section are all provided at a frontward facing surface of the housing.

2. The projection system according to claim 1, wherein the fan causes the air to flow along an outer surface of the projector body in an exterior of the channel in addition to an interior of the channel.

3. The projection system according to claim 1, wherein
the fan overlaps with the projector body when viewed in the air delivering direction of the fan.

4. The projection system according to claim 1, further comprising
a heat generator that is housed in the housing and is an element different from the projector body,
wherein an air delivery path that extends along an outer surface of the projector body from the intake section to a suction section of the fan is provided in the housing, and
the heat generator is disposed in the air delivery path.

5. The projection system according to claim 1, wherein
the outflow port is located at a position shifted frontward from an intake port of the projector body.
